(19) United States
(12) Patent Application Publication
(10) Pub. No.: US 2026/0153560 A1
(43) Pub. Date: Jun. 4, 2026

(54) ELECTRONIC DEVICE AND TEST METHOD AND SEMICONDUCTOR DEVICE

(71) Applicant: MEDIATEK INC., Hsinchu City (TW)

(72) Inventors: Hsiang-An CHEN, Hsinchu City (TW); Po-Chao TSAO, Hsinchu City (TW); Buo-Chin HSU, Hsinchu City (TW); Cheng-Tien WAN, Hsinchu City (TW); Ming-Cheng LEE, Hsinchu City (TW); Tung-Hsing LEE, Hsinchu City (TW)

(21) Appl. No.: 19/351,527

(22) Filed: Oct. 7, 2025

Related U.S. Application Data
(60) Provisional application No. 63/726,630, filed on Dec. 1, 2024.

(51) Int. Cl. G01R 31/28; H01L 21/66

(52) U.S. Cl. CPC G01R 31/2884; H10P 74/273

(57) ABSTRACT

An electronic device for testing a semiconductor device is provided. The semiconductor device includes a first metal layer, a second metal layer, a first conductive via element, and a first grounding via element. The first conductive via element is coupled between the first metal layer and the second metal layer. The first grounding via element is coupled to a ground voltage, and is disposed adjacent to the first conductive via element. The electronic device includes a detector and a processor. The detector detects a first floating area associated with the first metal layer, a first distance between the first conductive via element and the first grounding via element, and a first contact area between the second metal layer and the first conductive via element. The processor is coupled to the detector. The processor performs a first layout verification process on the second metal layer.

### CROSS REFERENCE TO RELATED APPLICATIONS

This application claims the benefit of U.S. Provisional Application No. 63/726,630, filed on Dec. 1, 2024, the entirety of which is incorporated by reference herein.

### BACKGROUND OF THE INVENTION

### Field of the Invention

The disclosure generally relates to an electronic device, and more specifically, it relates to an electronic device for reducing the probability of IC (Integrated Circuit) failure.

### Description of the Related Art

The antenna effect, more formally known as plasma induced gate oxide damage, is an effect that can potentially cause yield and reliability problems during the manufacture of MOS (Metal-Oxide-Semiconductor) integrated circuits. Accordingly, there is a need to propose a novel solution for solving the problem of the prior art.

### BRIEF SUMMARY OF THE INVENTION

In an exemplary embodiment, the disclosure is directed to an electronic device for testing a semiconductor device. The semiconductor device includes a first metal layer, a second metal layer, a first conductive via element, and a first grounding via element. The first conductive via element is coupled between the first metal layer and the second metal layer. The first grounding via element is coupled to a ground voltage, and is disposed adjacent to the first conductive via element. The electronic device includes a detector and a processor. The detector detects a first floating area associated with the first metal layer, a first distance between the first conductive via element and the first grounding via element, and a first contact area between the second metal layer and the first conductive via element. The processor is coupled to the detector. The processor performs the first layout verification process on the second metal layer according to the first floating area, the first distance, the first contact area and the first layout criterion.

In some embodiments, the processor performs the first layout verification process to compare the first antenna-sanity parameter with the first layout criterion. The first antenna-sanity parameter is calculated by the processor using the following equation:

$$T 1 = \frac{A 1}{C 1} \cdot \frac{1}{{( R 1 )}^{N}}$$

where “T1” represents the first antenna-sanity parameter, “A1” represents the first floating area, “C1” represents the first contact area, “R1” represent the first distance, and “N” represents a first positive number.

In some embodiments, if the first antenna-sanity parameter is smaller than or equal to the first layout criterion, the processor will determine that the first layout verification process is passed. If the first antenna-sanity parameter is greater than the first layout criterion, the processor will determine that the first layout verification process is unpassed.

In some embodiments, the first positive number is equal to 1 or 2.

In some embodiments, the semiconductor device further includes a third metal layer, a second conductive via element, and a second grounding via element. The second conductive via element is coupled between the second metal layer and the third metal layer. The second grounding via element is coupled to the ground voltage, and is disposed adjacent to the second conductive via element. The detector further detects a second floating area associated with the second metal layer, a second distance between the second conductive via element and the second grounding via element, and a second contact area between the third metal layer and the second conductive via element. The processor further performs a second layout verification process on the third metal layer according to the first floating area, the second floating area, the second distance, the second contact area and a second layout criterion.

In some embodiments, the processor performs the second layout verification process to compare a second antenna-sanity parameter with the second layout criterion. The second antenna-sanity parameter is calculated by the processor using the following equation:

$$T 2 = \frac{A 1 + A 2}{C 2} \cdot \frac{1}{{( R 2 )}^{M}}$$

where “T2” represents the second antenna-sanity parameter, “A1” represents the first floating area, “A2” represents the second floating area, “C2” represents the second contact area, “R2” represent the second distance, and “M” represents a second positive number.

In some embodiments, if the second antenna-sanity parameter is smaller than or equal to the second layout criterion, the processor will determine that the second layout verification process is passed. If the second antenna-sanity parameter is greater than the second layout criterion, the processor will determine that the second layout verification process is unpassed.

In some embodiments, the second positive number is equal to 1 or 2.

In another exemplary embodiment, the invention is directed to a test method that includes the steps of: providing a first metal layer, a second metal layer, a first conductive via element and a first grounding via element, wherein the first conductive via element is coupled between the first metal layer and the second metal layer, and wherein the first grounding via element is coupled to a ground voltage and is disposed adjacent to the first conductive via element; detecting a first floating area associated with the first metal layer; detecting a first distance between the first conductive via element and the first grounding via element; detecting a first contact area between the second metal layer and the first conductive via element; and performing a first layout verification process on the second metal layer according to the first floating area, the first distance, the first contact area and a first layout criterion.

### BRIEF DESCRIPTION OF DRAWINGS

The invention can be more fully understood by reading the subsequent detailed description and examples with references made to the accompanying drawings, wherein:

FIG. 1A is a top view of a semiconductor device and an electronic device according to an embodiment of the invention;

FIG. 1B is a side view of a semiconductor device according to an embodiment of the invention;

FIG. 2A is a top view of a semiconductor device and an electronic device according to an embodiment of the invention;

FIG. 2B is a side view of a semiconductor device according to an embodiment of the invention;

FIG. 3 is a top view of a semiconductor device according to an embodiment of the invention; and

FIG. 4 is a flowchart of a test method according to an embodiment of the invention.

### DETAILED DESCRIPTION OF THE INVENTION

In order to illustrate the purposes, features and advantages of the invention, the embodiments and figures of the invention are shown in detail as follows.

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. The term “substantially” means the value is within an acceptable error range. One skilled in the art can solve the technical problem within a predetermined error range and achieve the proposed technical performance. Also, the term “couple” is intended to mean either an indirect or direct electrical connection. Accordingly, if one device is coupled to another device, that connection may be through a direct electrical connection, or through an indirect electrical connection via other devices and connections.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

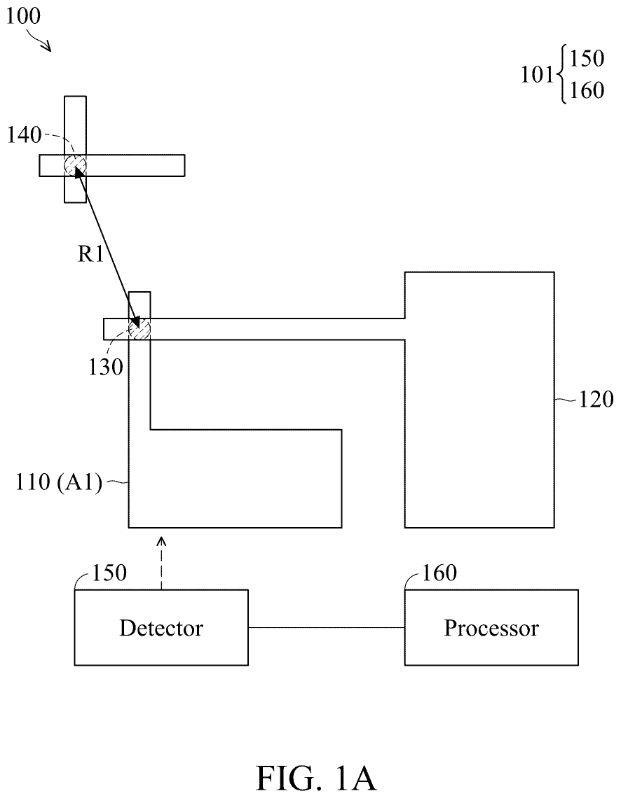

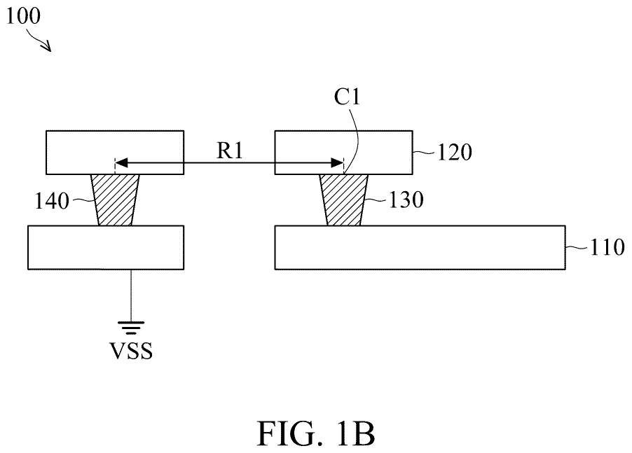

FIG. 1A is a top view of a semiconductor device 100 and an electronic device 101 according to an embodiment of the invention. FIG. 1B is a side view of the semiconductor device 100 according to an embodiment of the invention. Please refer to FIG. 1A and FIG. 1B together. In the embodiment of FIG. 1A and FIG. 1B, the semiconductor device 100 includes a first metal layer 110, a second metal layer 120, a first conductive via element 130, and a first grounding via element 140. It should be understood that the semiconductor device 100 may further include other components, such as a silicon substrate, a P-doping layer, and an N-doping layer, although they are not displayed in FIG. 1A and FIG. 1B.

The shapes and types of the first metal layer 110 and the second metal layer 120 are not limited in the invention. For example, the first metal layer 110 and the second metal layer 120 may be positioned on two different planes, which may be substantially parallel to each other. In some embodiments, the first metal layer 110 and the second metal layer 120 may be two vertically adjacent metal layers within a multiple-metal-layer structure, such as a backside metallization structure in a semiconductor chip. In other words, there may be additional metal layers disposed under and coupled to the first metal layer 110. In embodiments where the semiconductor device 100 is a semiconductor chip, the first metal layer 110 add/or the second metal layer 120 may have a metal minimum pitch of equal to or less than 80 nm (such as metal layers M1 or M2). In some embodiments, the first metal layer 110 and/or the second metal layer 120 may have a metal minimum pitch of greater than 80 nm, such as top metal layers away from a substrate body of the semiconductor device 100.

The first conductive via element 130 is coupled between the first metal layer 110 and the second metal layer 120. The first grounding via element 140 is coupled to a ground voltage VSS, and is disposed adjacent to the first conductive via element 140. For example, the first grounding via element 140 may be grounded through metal layers and vias stacked below and all the way towards active regions (or called OD regions) of the substrate body underneath. In some embodiments, the first conductive via element 130 and the first grounding via element 140 are positioned on the same layer. It should be noted that the term “adjacent” or “close” over the disclosure means that the distance (spacing) between two corresponding elements is smaller than a predetermined distance (e.g., 10 mm or the shorter), but often does not mean that the two corresponding elements directly touch each other (i.e., the aforementioned distance/spacing between them is reduced to 0). In embodiments as shown in FIGS. 1A and 1B, the first metal layer 110, the second metal layer 120 and the first conductive via element 130 are electrically floating, where at the level of the conductive via element 130, the first grounding via element 140 is considered as a nearest discharging point related to the conductive via element 130.

The electronic device 101 is used for testing the semiconductor device 100. For example, the electronic device 101 may be implemented with a hardware circuit, a software program, or a combination thereof. Specifically, the electronic device 101 includes a detector 150 and a processor 160. The detector 150 can detect a first floating area A1 associated with the first metal layer 110, a first distance R1 between the first conductive via element 130 and the first grounding via element 140, and a first contact area C1 between the second metal layer 120 and the first conductive via element 130. In embodiments where the first metal layer 110 is not the bottommost metal layer (i.e., additional metal layer(s) exists and stacked under the first metal layer 110), the first floating area A1 may be defined as an accumulated floating area of the first metal layer 110 and the metal layers (if existed) stacked and coupled underneath and electrically floating. The first distance R1 may be a center-to-center distance between the first conductive via element 130 and the second conductive via element 140 as illustrated in FIG. 1B. In some other embodiments, the first distance R1 may be determined as an edge-to-edge or the nearest distance between the first conductive via element 130 and the second conductive via element 140. The first contact area C1 may be equivalent to the top area of the first conductive via element 130, rather than the bottom area of the first conductive via element 130. The processor 160 is coupled to the detector 150. The processor 160 can perform a first layout verification process on the second metal layer 120 according to the first floating area A1, the first distance R1, the first contact area C1, and a first layout criterion. For example, the first layout criterion may be a predetermined value stored in the processor 160.

In some embodiments, the processor 160 can perform the first layout verification process to compare a first antenna-sanity parameter with the first layout criterion. For example, the first antenna-sanity parameter may be calculated by the processor using equation (1):

$$T 1 = \frac{A 1}{C 1} \cdot \frac{1}{{( R 1 )}^{N}} \qquad ( 1 )$$

where “T1” represents the first antenna-sanity parameter, “A1” represents the first floating area, “C1” represents the first contact area, “R1” represent the first distance, and “N” represents a first positive number.

In some embodiments, if the first antenna-sanity parameter is smaller than or equal to the first layout criterion, the processor 160 will determine that the first layout verification process is passed. In alternative embodiments, if the first antenna-sanity parameter is greater than the first layout criterion, the processor 160 will determine that the first layout verification process is unpassed. In such scenario, the risk of induced antenna effect IC failure due to accumulated charges during manufacturing process may be high and unacceptable.

In some embodiments, the first positive number (N) can be a positive integer such as 1 or 2. For example, if the first positive number is set to 1, the first layout criterion may be selected from 80000 to 1200000, and if the first positive number is set to 2, the first layout criterion may be selected from 20000 to 400000, but it is not limited thereto.

In some embodiments, the first layout criterion is adjustable according to Table I as follows:

TABLE I

| | | |
|---|---|---|
| Minimum Pitch of First | First Positive | First Layout |
| Metal Layer | Number | Criterion |

| ≤80 | nm | N = 1 | 350000 to 1200000 |
|---|---|---|---|
| | | N = 2 | 100000 to 400000 |
| >80 | nm | N = 1 | 80000 to 140000 |

| | |
|---|---|
| N = 2 | 20000 to 50000 |

With such a design, since the first distance R1 is considered during the first layout verification process, it can provide a 3D (Three-Dimensional) examining methodology for IC (Integrated Circuit) designs with more circumspect specifications. According to practical measurements, the proposed electronic device 101 of the invention can significantly reduce the probability of IC failure or damage caused by a non-ideal antenna effect of the semiconductor device 100. Therefore, the performance of the semiconductor device 100 can be effectively improved.

The following embodiments will introduce different configurations and detail structural features of the semiconductor device 100 and the electronic device 101. It should be understood that these figures and descriptions are merely exemplary, rather than limitations of the invention.

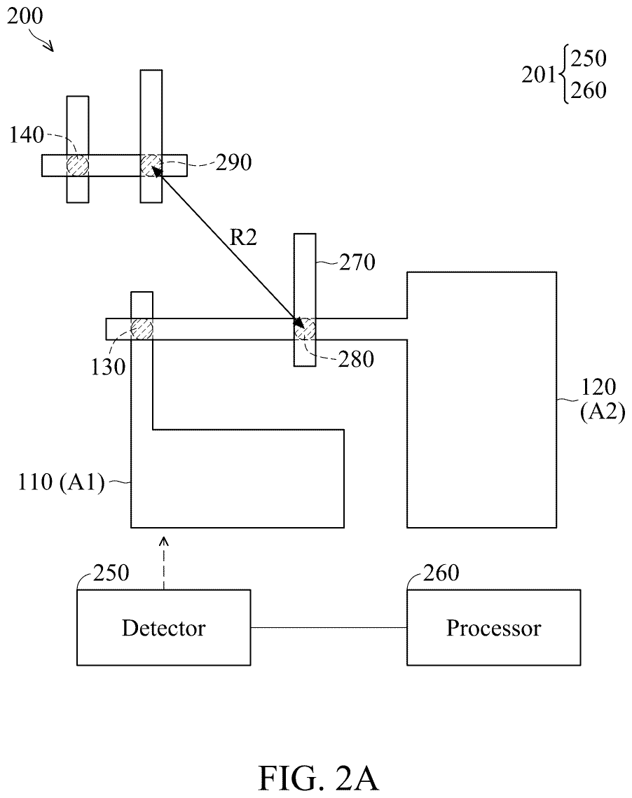

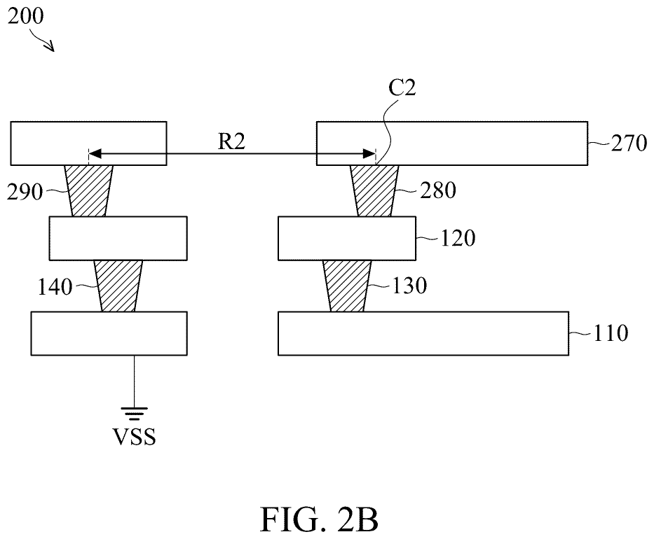

FIG. 2A is a top view of a semiconductor device 200 and an electronic device 201 according to an embodiment of the invention. FIG. 2B is a side view of the semiconductor device 200 according to an embodiment of the invention. Please refer to FIG. 2A and FIG. 2B together. FIG. 2A and FIG. 2B are similar to FIG. 1A and FIG. 1B, respectively. In the embodiment of FIG. 2A and FIG. 2B, the electronic device 201 for testing the semiconductor device 200 includes a detector 250 and a processor 260. In addition to the first metal layer 110, the second metal layer 120, the first conductive via element 130, and the first grounding via element 140 as mentioned above, the semiconductor device 200 further includes a third metal layer 270 disposed above the second metal layer 120, a second conductive via element 280, and a second grounding via element 290. For example, the first metal layer 110, the second metal layer 120, and the third metal layer 270 may be positioned on three different planes, which may be substantially parallel to each other.

The second conductive via element 280 is coupled between the second metal layer 120 and the third metal layer 270, such that the first metal layer 110, the first conductive via element 130, the second metal layer 120, the second conductive via element 280 and the third metal layer 270 are electrically floating. The second grounding via element 290 is also coupled to the first grounding via element 140, and is disposed adjacent to the second conductive via element 280. In some embodiments, the second conductive via element 280 and the second grounding via element 290 are positioned on the same layer, where the second grounding via element 290 is considered as a nearest discharging point related to the second conductive via element 280. The detector 250 can detect the first floating area A1 associated with the first metal layer 110, a second floating area A2 associated with the second metal layer 120, a second distance R2 between the second conductive via element 280 and the second grounding via element 290, and a second contact area C2 between the third metal layer 270 and the second conductive via element 280. For example, the second contact area C2 may be equivalent to the top area of the second conductive via element 280, rather than the bottom area of the second conductive via element 280. The processor 260 can further perform a second layout verification process on the third metal layer 130 according to the first floating area A1, the second floating area A2, the second distance R2, the second contact area C2, and a second layout criterion. For example, the second layout criterion may be another predetermined value stored in the processor 260.

In some embodiments, the processor 260 can perform the second layout verification process to compare a second antenna-sanity parameter with the second layout criterion. For example, the second antenna-sanity parameter may be calculated by the processor 260 using equation (2):

$$T 2 = \frac{A 1 + A 2}{C 2} \cdot \frac{1}{{( R 2 )}^{M}} \qquad ( 2 )$$

where “T2” represents the second antenna-sanity parameter, “A1” represents the first floating area, “A2” represents the second floating area, “C2” represents the second contact area, “R2” represent the second distance, and “M” represents a second positive number. Here in the equation (2), A1+A2 means the total accumulated floating area associated with the first metal layer 110 and the second metal layer 120. Similar to the previously described embodiments, when the first metal layer 110 is not the bottommost metal layer (i.e., additional metal layer(s) exists and stacked under the first metal layer 110), the first floating area A1 may be defined as an accumulated floating area of the first metal layer 110 and the metal layers (if existed) stacked and coupled underneath and electrically floating. In such embodiments, A1+A2 in the equation (2) may be referred to as the total accumulated floating area associated with the first metal layer 110, the second metal layer 120 and the metal layers stacked and coupled underneath and electrically floating.

In some embodiments, if the second antenna-sanity parameter is smaller than or equal to the second layout criterion, the processor 260 will determine that the second layout verification process is passed. In alternative embodiments, if the second antenna-sanity parameter is greater than the second layout criterion, the processor 260 will determine that the second layout verification process is unpassed.

In some embodiments, the second positive number (M) may be a positive integer such as 1 or 2. For example, if the second positive number is set to 1, the second layout criterion may be selected from 80000 to 1200000, and if the second positive number is set to 2, the second layout criterion may be selected from 20000 to 400000, but it is not limited thereto. According to practical measurements, the performance of the semiconductor device 200 can be further improved because both the first layout verification process and the second layout verification process are applied. Other features of the semiconductor device 200 and the electronic device 201 of FIGS. 2A and 2B are similar to those of the semiconductor device 100 and the electronic device 101 of FIG. 1A and FIG. 1B. Therefore, the two embodiments can achieve similar levels of performance.

In some embodiments, the second layout criterion is adjustable according to Table II as follows:

TABLE II

| Minimum Pitch of Second | | Second Positive | Second Layout |
|---|---|---|---|
| Metal Layer | | Number | Criterion |
| ≤80 | nm | M = 1 | 350000 to 1200000 |
| | | M = 2 | 100000 to 400000 |
| >80 | nm | M = 1 | 80000 to 140000 |

| | |
|---|---|
| M = 2 | 20000 to 50000 |

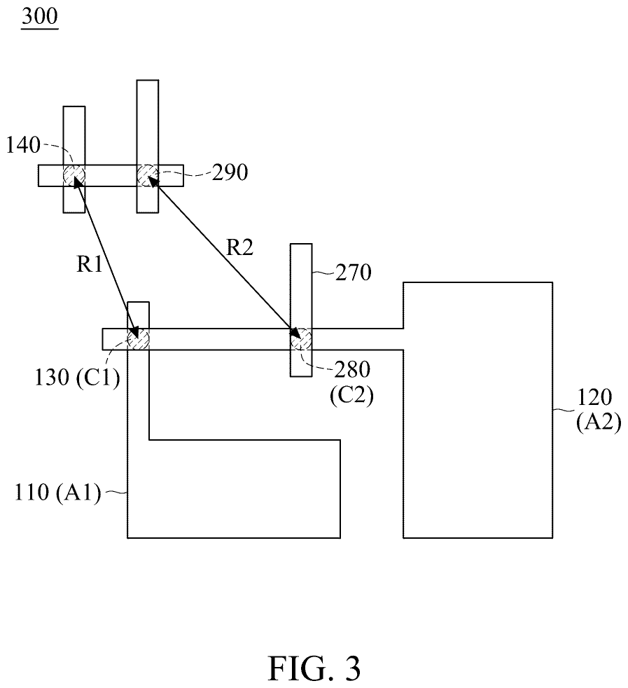

FIG. 3 is a top view of a semiconductor device 300 according to an embodiment of the invention. FIG. 3 is similar to FIG. 2A and FIG. 2B. In the embodiment of FIG. 3, the semiconductor device 300 includes a first metal layer 110, a second metal layer 120, a first conductive via element 130, a first grounding via element 140, a third metal layer 270, a second conductive via element 280, and a second grounding via element 290. Their arrangements have been illustrated in the previous embodiments. The first metal layer 110 has a first floating area A1. The second metal layer 120 has a second floating area A2. A first distance R1 is defined between the first conductive via element 130 and the first grounding via element 140. A second distance R2 is defined between the second conductive via element 280 and the second grounding via element 290. A first contact area C1 is defined between the second metal layer 120 and the first conductive via element 130. A second contact area C2 is defined between the third metal layer 270 and the second conductive via element 280.

The second metal layer 120 is capable of passing a first layout verification process. The first layout verification process is performed according to the first floating area A1, the first distance R1, the first contact area C1, and a first layout criterion. For example, the first layout verification process may be performed to compare the first antenna-sanity parameter with the first layout criterion, and the first antenna-sanity parameter may be calculated using the above equation (1).

The third metal layer 270 is capable of passing a second layout verification process. The second layout verification process is performed according to the first floating area A1, the second floating area A2, the second distance R2, the second contact area C2, and the second layout criterion. For example, the second layout verification process may be performed to compare a second antenna-sanity parameter with the second layout criterion, and the second antenna-sanity parameter may be calculated using the above equation (2).

It should be noted that the probability of IC failure (caused by a non-ideal antenna effect) of the proposed semiconductor device 300 of the invention is very low because both the first layout verification process and the second layout verification process are passed. Other features of the semiconductor device 300 of FIG. 3 are similar to those of the semiconductor device 200 and of FIG. 2A and FIG. 2B. Therefore, the two embodiments can achieve similar levels of performance. As previously noted, in some other embodiments, the semiconductor device 300 includes more metal layers and more conductive via elements, and they are arranged and verified in a similar way.

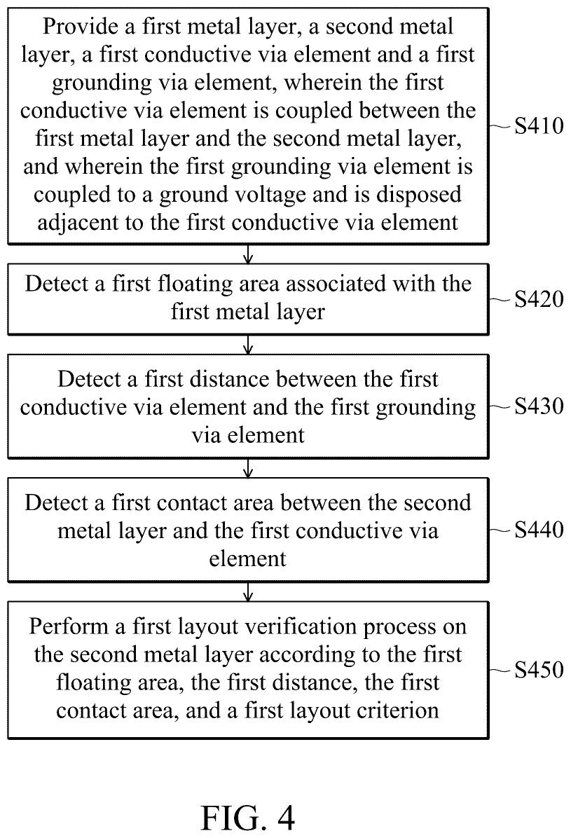

FIG. 4 is a flowchart of a test method according to an embodiment of the invention. The aforementioned test method includes the following steps. To begin, in the step S410, a first metal layer, a second metal layer, a first conductive via element, and a first grounding via element are provided. The first conductive via element is coupled between the first metal layer and the second metal layer. The first grounding via element is coupled to a ground voltage, and is disposed adjacent to the first conductive via element. In the step S420, a first floating area associated with the first metal layer is detected. In the step S430, a first distance between the first conductive via element and the first grounding via element is detected. In the step S440, a first contact area between the second metal layer and the first conductive via element is detected. Finally, in the step S450, a first layout verification process is performed on the second metal layer according to the first floating area, the first distance, the first contact area, and a first layout criterion. It should be noted that the above steps are not required to be performed in order, and every feature of the embodiments of FIGS. 1A, 1B, 2A, 2B and 3 may be applied to the test method of FIG. 4.

The invention proposes a novel electronic device, a novel semiconductor device, and a novel test method thereof. Compared to the conventional design, the invention has at least the advantages of effectively suppressing the non-ideal antenna effect, and therefore it is suitable for application in a variety of devices.

Note that the above element parameters are not limitations of the invention. A designer can fine-tune these settings or values according to different requirements. It should be understood that the electronic device, the semiconductor device, and the test method of the invention are not limited to the configurations of FIGS. 1A to 4. The invention may merely include any one or more features of any one or more embodiments of FIGS. 1A to 4. In other words, not all of the features displayed in the figures should be implemented in the electronic device, the semiconductor device, and the test method of the invention.

The method of the invention, or certain aspects or portions thereof, may take the form of program code (i.e., executable instructions) embodied in tangible media, such as floppy diskettes, CD-ROMS, hard drives, or any other machine-readable storage medium, wherein, when the program code is loaded into and executed by a machine such as a computer, the machine thereby becomes an apparatus for practicing the methods. The methods may also be embodied in the form of program code transmitted over some transmission medium, such as electrical wiring or cabling, through fiber optics, or via any other form of transmission, wherein, when the program code is received and loaded into and executed by a machine such as a computer, the machine becomes an apparatus for practicing the disclosed methods. When implemented on a general-purpose processor, the program code combines with the processor to provide a unique apparatus that operates analogously to application-specific logic circuits.

Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An electronic device for testing a semiconductor device, the semiconductor device comprising a first metal layer, a second metal layer, a first conductive via element and a first grounding via element, the first conductive via element being coupled between the first metal layer and the second metal layer, the first grounding via element being coupled to a ground voltage and disposed adjacent to the first conductive via element, and the electronic device comprising:
a detector, detecting a first floating area associated with the first metal layer, a first distance between the first conductive via element and the first grounding via element, and a first contact area between the second metal layer and the first conductive via element; and
a processor, coupled to the detector, wherein the processor performs a first layout verification process on the second metal layer according to the first floating area, the first distance, the first contact area and a first layout criterion.

2. The electronic device as claimed in claim 1, wherein the processor performs the first layout verification process to compare a first antenna-sanity parameter with the first layout criterion, and the first antenna-sanity parameter is calculated by the processor using the following equation:
$$T 1 = \frac{A 1}{C 1} \cdot \frac{1}{{( R 1 )}^{N}}$$
where “T1” represents the first antenna-sanity parameter, “A1” represents the first floating area, “C1” represents the first contact area, “R1” represent the first distance, and “N” represents a first positive number.

3. The electronic device as claimed in claim 2, wherein if the first antenna-sanity parameter is smaller than or equal to the first layout criterion, the processor determines that the first layout verification process is passed, and if the first antenna-sanity parameter is greater than the first layout criterion, the processor determines that the first layout verification process is unpassed.

4. The electronic device as claimed in claim 2, wherein the first positive number is equal to 1 or 2.

5. The electronic device as claimed in claim 1, wherein the semiconductor device further comprises a third metal layer, a second conductive via element and a second grounding via element, the second conductive via element is coupled between the second metal layer and the third metal layer, the second grounding via element is coupled to the ground voltage and is disposed adjacent to the second conductive via element, the detector further detects a second floating area associated with the second metal layer, a second distance between the second conductive via element and the second grounding via element and a second contact area between the third metal layer and the second conductive via element, and the processor further performs a second layout verification process on the third metal layer according to the first floating area, the second floating area, the second distance and a second layout criterion.

6. The electronic device as claimed in claim 5, wherein the processor performs the second layout verification process to compare a second antenna-sanity parameter with the second layout criterion, and the second antenna-sanity parameter is calculated by the processor using the following equation:
$$T 2 = \frac{A 1 + A 2}{C 2} \cdot \frac{1}{{( R 2 )}^{M}}$$
where “T2” represents the second antenna-sanity parameter, “A1” represents the first floating area, “A2” represents the second floating area, “C2” represents the second contact area, “R2” represent the second distance, and “M” represents a second positive number.

7. The electronic device as claimed in claim 6, wherein if the second antenna-sanity parameter is smaller than or equal to the second layout criterion, the processor determines that the second layout verification process is passed, and if the second antenna-sanity parameter is greater than the second layout criterion, the processor determines that the second layout verification process is unpassed.

8. The electronic device as claimed in claim 6, wherein the second positive number is equal to 1 or 2.

9. A test method, comprising the steps of:
providing a first metal layer, a second metal layer, a first conductive via element and a first grounding via element, wherein the first conductive via element is coupled between the first metal layer and the second metal layer, and wherein the first grounding via element is coupled to a ground voltage and is disposed adjacent to the first conductive via element;
detecting a first floating area associated with the first metal layer;
detecting a first distance between the first conductive via element and the first grounding via element;
detecting a first contact area between the second metal layer and the first conductive via element; and
performing a first layout verification process on the second metal layer according to the first floating area, the first distance, the first contact area and a first layout criterion.

10. The test method as claimed in claim 9, wherein the first layout verification process comprises:
comparing a first antenna-sanity parameter with the first layout criterion, wherein the first antenna-sanity parameter is calculated using the following equation:
$$T 1 = \frac{A 1}{C 1} \cdot \frac{1}{{( R 1 )}^{N}}$$
where “T1” represents the first antenna-sanity parameter, “A1” represents the first floating area, “C1” represents the first contact area, “R1” represent the first distance, and “N” represents a first positive number.

11. The test method as claimed in claim 10, further comprising:
if the first antenna-sanity parameter is smaller than or equal to the first layout criterion, determining that the first layout verification process is passed; and
if the first antenna-sanity parameter is greater than the first layout criterion, determining that the first layout verification process is unpassed.

12. The test method as claimed in claim 10, wherein the first positive number is equal to 1 or 2.

13. The test method as claimed in claim 9, further comprising:
providing a third metal layer, a second conductive via element and a second grounding via element, wherein the second conductive via element is coupled between the second metal layer and the third metal layer, and wherein the second grounding via element is coupled to the ground voltage and is disposed adjacent to the second conductive via element;
detecting a second floating area associated with the second metal layer;
detecting a second distance between the second conductive via element and the second grounding via element;
detecting a second contact area between the third metal layer and the second conductive via element; and
performing a second layout verification process on the third metal layer according to the first floating area, the second floating area, the second distance, the second contact area and a second layout criterion.

14. The test method as claimed in claim 13, wherein the second layout verification process comprises:
comparing a second antenna-sanity parameter with the second layout criterion, wherein the second antenna-sanity parameter is calculated using the following equation:
$$T 2 = \frac{A 1 + A 2}{C 2} \cdot \frac{1}{{( R 2 )}^{M}}$$
wherein “T2” represents the second antenna-sanity parameter, “A1” represents the first floating area, “A2” represents the second floating area, “C2” represents the second contact area, “R2” represent the second distance, and “M” represents a second positive number.

15. The test method as claimed in claim 14, further comprising:
if the second antenna-sanity parameter is smaller than or equal to the second layout criterion, determining that the second layout verification process is passed; and
if the second antenna-sanity parameter is greater than the second layout criterion, determining that the second layout verification process is unpassed.

16. The test method as claimed in claim 14, wherein the second positive number is equal to 1 or 2.
